(19) United States
(12) Patent Application Publication
(10) Pub. No.: US 2003/0147296 A1
(43) Pub. Date: Aug. 7, 2003

(54) Semiconductor memory unit

(75) Inventor: Takanobu Suzuki, Tokyo (JP)

Correspondence Address: MCDERMOTT, WILL & EMERY, 600 13th Street, N.W., WASHINGTON, DC, 20005-3096, US

(73) Assignee: Mitsubishi Denki Kabushiki Kaisha

(21) Appl. No.: 10/200,402

(22) Filed: Jul. 23, 2002

(30) Foreign Application Priority Data
Feb. 5, 2002 (JP) 2002-028294

(51) Int. Cl. G11C 8/00

(52) U.S. Cl. 365/230.03

(57) ABSTRACT

A bank switching type semiconductor memory unit having a plurality of memory cell array banks, including a pass/fail decision circuit which is provided for a plurality of neighboring ones of the memory cell array banks so as to make a pass/fail decision on the neighboring ones of the memory cell array banks in a multi-bit test.

### BACKGROUND OF THE INVENTION

(Field of the Invention)

The present invention generally relates to a test mode of a dynamic random access memory (DRAM) and more particularly, to a multi-bit test of the DRAM.

(Description of the Prior Art)

A conventional DRAM shown in FIG. 10 includes pairs of memory cell array banks 5A to 5D, column decoders 6, input-output circuits 7, row decoders 8, a data bus pair 10 and a data input-output circuit 16. There is a multi-bit test in test modes of the DRAM. In ordinary operation of the conventional DRAM of FIG. 10, write and read of 1-bit data inputted from a data pad EXTDQ are performed on one memory cell. On the other hand, in the multi-bit test, 1-bit data inputted from the data pad EXTDQ is written on a plurality of memory cells simultaneously and read-out data from a plurality of the memory cells is outputted to the single data pad EXTDQ.

Difference between the multi-bit test and ordinary operation is described with reference to FIG. 11 showing a portion of the memory cell array bank 5B of FIG. 10. In the memory cell bank 5B of FIG. 11, memory cell arrays 120A to 120D are provided and a sense amplifier 121 is provided for each of the memory cell arrays 120A to 120D. Meanwhile, the data input-output circuit 16 has a data input circuit (not shown) and a data output circuit 140 of FIG. 13. In write of ordinary operation, 1-bit data inputted from the data input circuit of the data input-output circuit 16 is delivered by the data bus pair 10 so as to be written in a memory cell disposed at a point of intersection of an inputted row address and an inputted column address. For example, in the memory cell array 120A of FIG. 11, data is written in a memory cell A at which a word line WL obtained by decoding the row address intersects with a column selection line CSLA obtained by decoding the column address.

On the other hand, in the multi-bit test, data inputted from the data input circuit of the data input-output circuit 16 is written in a plurality of memory cells simultaneously. For example, in FIG. 11, by concurrently activating four column selection lines CSLA to CSLD into which the column address has been decoded, data inputted from the data input circuit is simultaneously written in four memory cells, i.e., the memory cell A of the memory cell array 120A, a memory cell B of the memory cell array 120B, a memory cell C of the memory cell array 120C and a memory cell D of the memory cell array 120D.

In read of ordinary operation, data in a memory cell at which the word line WL obtained by decoding the row address intersects with a column selection line CSL obtained by decoding the column address is sequentially fed by the sense amplifier 121, the input-output circuit 7, the data bus pair 10 and the data output circuit 140 (FIG. 13) of the data input-output circuit 16 so as to be outputted.

On the other hand, in the multi-bit test, by simultaneously activating the four column selection lines CSLA to CSLD in the same manner as write operation, data in the memory cells A, B, C and D in FIG. 11 is fed from the sense amplifiers 121 to the input-output circuits 7 so as to be outputted to the same data bus pair 10. Here, the input-output circuit 7 has a pre-amplifier 180 of a latency shift circuit 220 of FIG. 16 and a data bus drive circuit 130 of FIG. 12. The data bus drive circuit 130 receives a signal PDD and its inverted signal ZPDD outputted from the pre-amplifier 180 and outputs a data bus signal DB and its inverted data bus signal ZDB, respectively.

In the data bus drive circuit 130 of the input-output circuit 7, in case data from the memory cell is at high level, the data bus signal DB is driven to high level and the inverted data bus signal ZDB is driven to a “Hi-Z” condition which represents a condition having a potential intermediate between the potential of “0” and the potential of “1”. On the other hand, in case data from the memory cell is at low level, the data bus signal DB is driven to the Hi-Z condition and the inverted data bus signal ZDB is driven to high level. Data from the four memory cells is subjected to wired OR in the data bus pair 10 and is fed to the data output circuit 140 (FIG. 13) of the data input-output circuit 16.

During write of the multi-bit test, the identical data is written in the four memory cells simultaneously. Hence, if there is no defect in the four memory cells, the four data read from the four memory cells are identical and thus, only one of the data bus signal DB and the inverted data bus signal ZDB is at high level. Namely, if the read-out data is at high level, the data bus signal DB is at high level and the inverted data bus signal ZDB is at low level (Hi-Z condition). On the contrary, if the read-out data is at low level, the data bus signal DB is at low level (Hi-Z condition) and the inverted data bus signal ZDB is at high level.

Meanwhile, if there is a defect in one of the four memory cells, both high-level read-out data and low-level read-out data exist, so that both of the data bus signal DB and the inverted data bus signal ZDB are at high level. In the data output circuit 140 of the data input-output circuit 16, a pass/fail decision is made on the four memory cells by using the data of the four memory cells, which is carried by the data bus pair 10. In the data output circuit 140, logic is designed such that a pass decision is made on the four memory cells when the data bus signal DB and the inverted data bus signal ZDB are at high level and at low level, respectively or at low level and at high level, respectively, while a fail decision is made on the four memory cells when both the data bus signal DB and the inverted data bus signal ZDB are at high level. FIGS. 14 and 15 are timing charts at the time of the pass decision and the fail decision in the multi-bit test of the conventional DRAM of FIG. 10, respectively.

If the multi-bit test is made as described above, a plurality of the memory cells can be tested concurrently and thus, test time of the DRAM can be shortened.

In the conventional multi-bit test, the data transmitted from the memory cell arrays to the data bus is subjected to wired OR on the data bus and a pass/fail decision on the memory cells is made in the data output circuit as described above. However, in the above described conventional multi-bit test, such a problem arises that operation of the multi-bit test becomes slower as wiring capacity of the data bus is increased. For example, if capacity of the data bus increases by 1 pF, the multi-bit test is delayed by about 0.7 ns. Meanwhile, if chip area of the DRAM and wiring length of the data bus increase due to increase of storage capacity in recent years, operating frequency of the multi-bit test drops further, so that period required for the multi-bit test becomes longer undesirably.

### SUMMARY OF THE INVENTION

Accordingly, an essential object of the present invention is to provide, with a view to eliminating the above mentioned drawbacks of prior art, a semiconductor memory unit in which a multi-bit test can be performed at high speed.

In order to accomplish this object of the present invention, a bank switching type semiconductor memory unit having a plurality of memory cell array banks, according to the present invention includes a pass/fail decision circuit which is provided for a plurality of neighboring ones of the memory cell array banks so as to make a pass/fail decision on the neighboring ones of the memory cell array banks in a multi-bit test.

### BRIEF DESCRIPTION OF THE DRAWINGS

This object and features of the present invention will become apparent from the following description taken in conjunction with the preferred embodiments thereof with reference to the accompanying drawings in which:

FIG. 1 is a diagram showing a circuit configuration of a semiconductor memory unit according to a first embodiment of the present invention;

FIG. 2 is a circuit diagram of a pass/fail decision circuit employed in the semiconductor memory unit of FIG. 1;

FIG. 3 is a timing chart at the time of a pass decision in a multi-bit test during operation of the semiconductor memory unit of FIG. 1 in a CAS latency 2;

FIG. 4 is a timing chart at the time of a fail decision in the multi-bit test during operation of the semiconductor memory unit of FIG. 1 in the CAS latency 2;

FIG. 5 is a circuit diagram of a data bus drive circuit employed in a semiconductor memory unit according to a second embodiment of the present invention;

FIG. 6 is a circuit diagram of a data output circuit employed in the semiconductor memory unit of FIG. 5;

FIG. 7 is a circuit diagram of a latency shift circuit employed in a semiconductor memory unit according to a third embodiment of the present invention;

FIG. 8 is a timing chart at the time of a pass decision in a multi-bit test during operation of the semiconductor memory unit of FIG. 7 in a CAS latency 3;

FIG. 9 is a timing chart at the time of a fail decision in the multi-bit test during operation of the semiconductor memory unit of FIG. 7 in the CAS latency 3;

FIG. 10 is a diagram showing a circuit configuration of a prior art semiconductor memory unit;

FIG. 11 is a fragmentary view of the prior art semiconductor memory unit of FIG. 10;

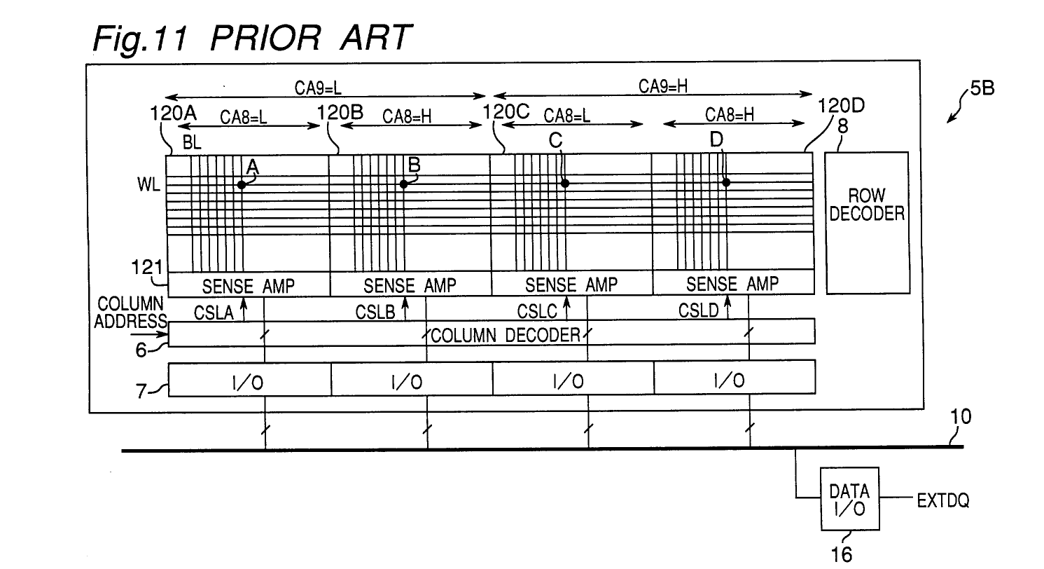

FIG. 12 is a circuit diagram of a data bus drive circuit employed in the prior art semiconductor memory unit of FIG. 10;

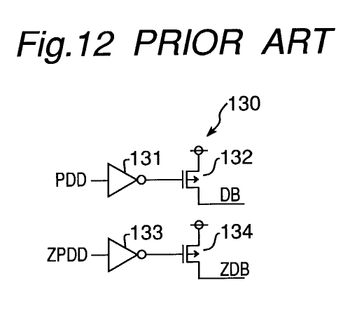

FIG. 13 is a circuit diagram of a data output circuit employed in the prior art semiconductor memory unit of FIG. 10;

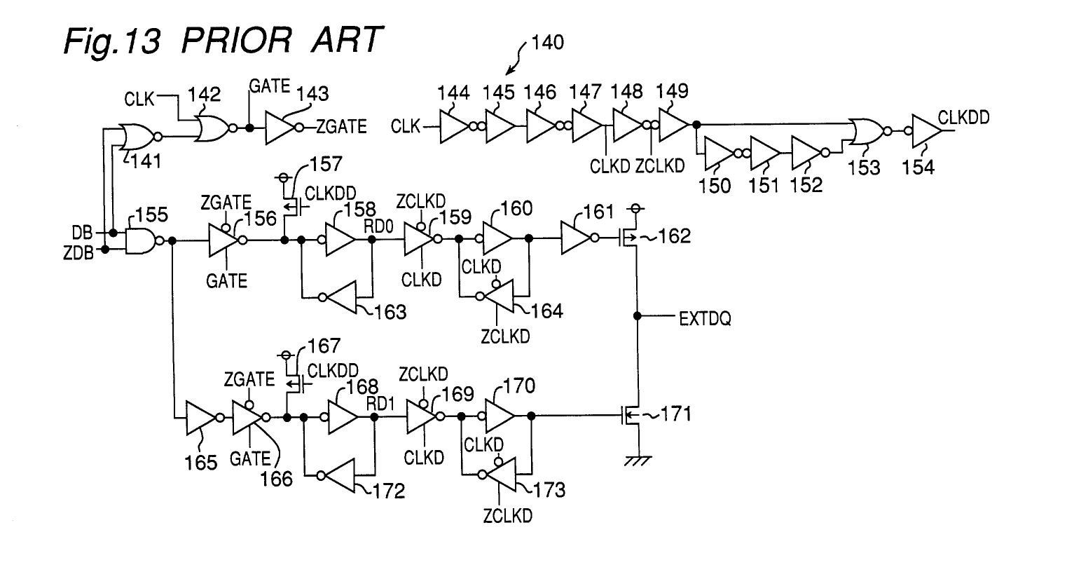

FIG. 14 is a timing chart at the time of a pass decision in a multi-bit test of the prior art semiconductor memory unit of FIG. 10;

FIG. 15 is a timing chart at the time of a fail decision in the multi-bit test of the prior art semiconductor memory unit of FIG. 10; and

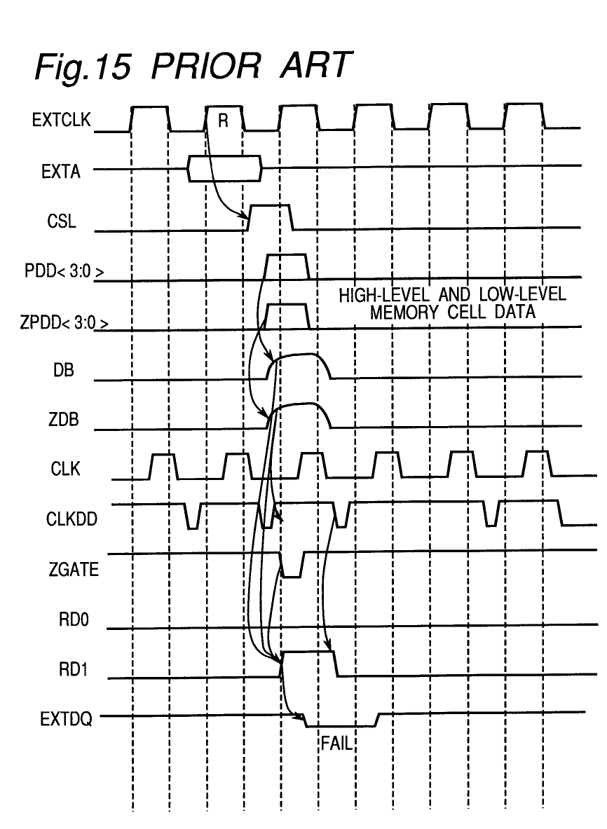

FIG. 16 is a circuit diagram of a latency shift circuit employed in the prior art semiconductor memory unit of FIG. 10.

Before the description of the present invention proceeds, it is to be noted that like parts are designated by like reference numerals throughout several views of the accompanying drawings.

### DETAILED DESCRIPTION OF THE INVENTION

Hereinafter, embodiments of the present invention are described with reference to the drawings.

(First Embodiment)

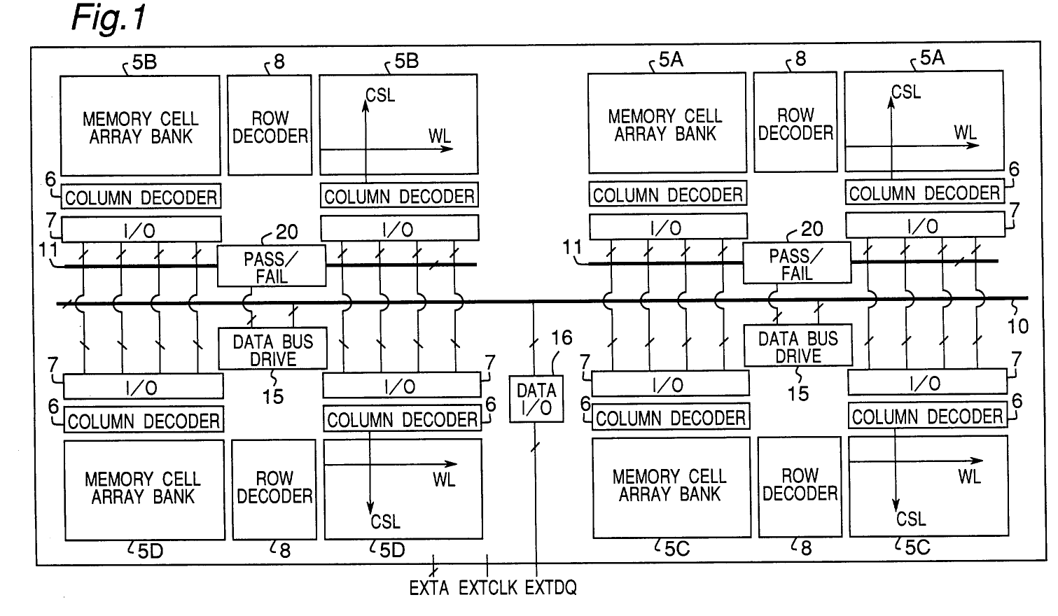

FIG. 1 shows a circuit configuration of a bank switching type DRAM acting as a semiconductor memory unit according to a first embodiment of the present invention. This DRAM includes pairs of neighboring memory cell array banks 5A to 5D, column decoders 6, input-output circuits 7, row decoders 8, a data bus pair 10, data bus drive circuits 15 and a data input-output circuit 16. Although not specifically shown, the data input-output circuit 16 includes a data input circuit and a data output circuit.

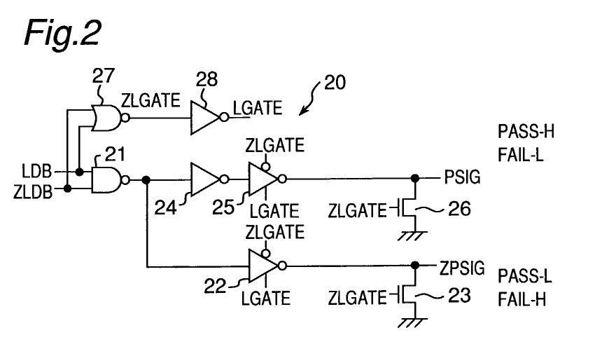

The DRAM of the present invention further includes a data bus pair 11 provided for each pair of the memory cell array banks 5A to 5D and a pass/fail decision circuit 20 provided on the data bus pair 11. The pass/fail decision circuit 20 performs wired OR on the data bus pair 11 and makes a pass/fail decision of a multi-bit test. As shown in FIG. 2, the pass/fail decision circuit 20 includes a NAND circuit 21 and an inverter 22 and outputs a signal PSIG in response to a signal LDB and its inverted signal ZLDB from the data bus pair 11. The signal PSIG is at high level and at low level at the time of a pass decision and a fail decision, respectively.

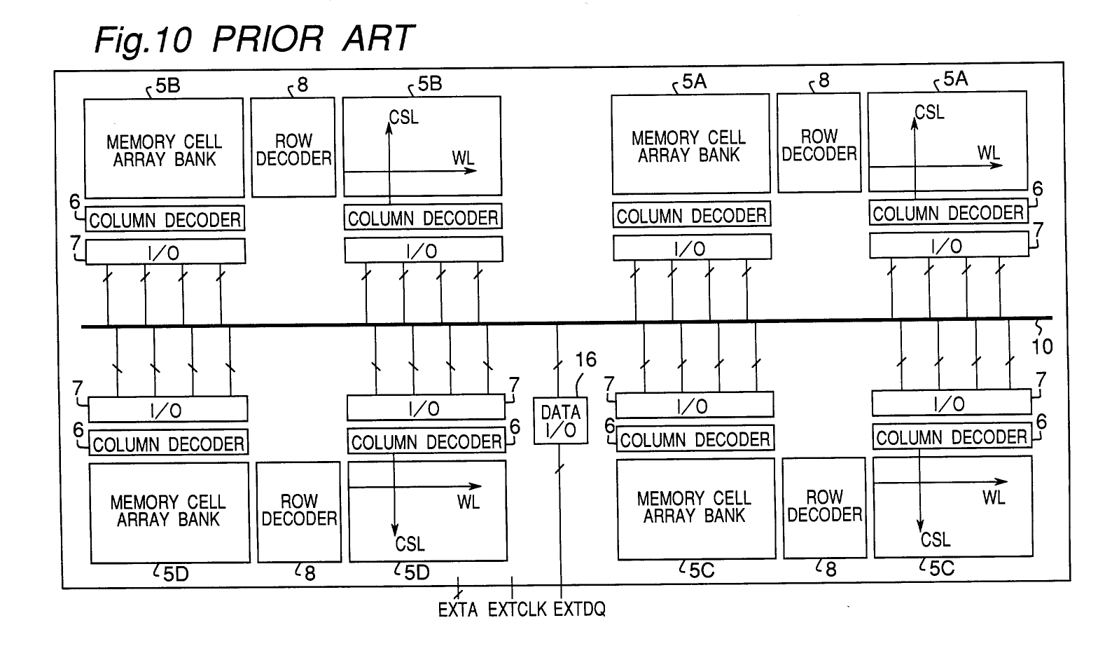

In this embodiment, since a pass/fail decision is made in the pass/fail decision circuit 20 in the banks in contrast with a multi-bit test of a conventional DRAM of FIG. 10, in which a pass/fail decision is made in a data output circuit of the data input-output circuit 16 by using data of a data bus pair 10, wiring length of the data bus pair 11 for performing wired OR is reduced to about a half of that of the conventional DRAM of FIG. 10, so that data of the data bus pair 11 reaches a CMOS level rapidly and thus, time period required for the pass/fail decision is shortened.

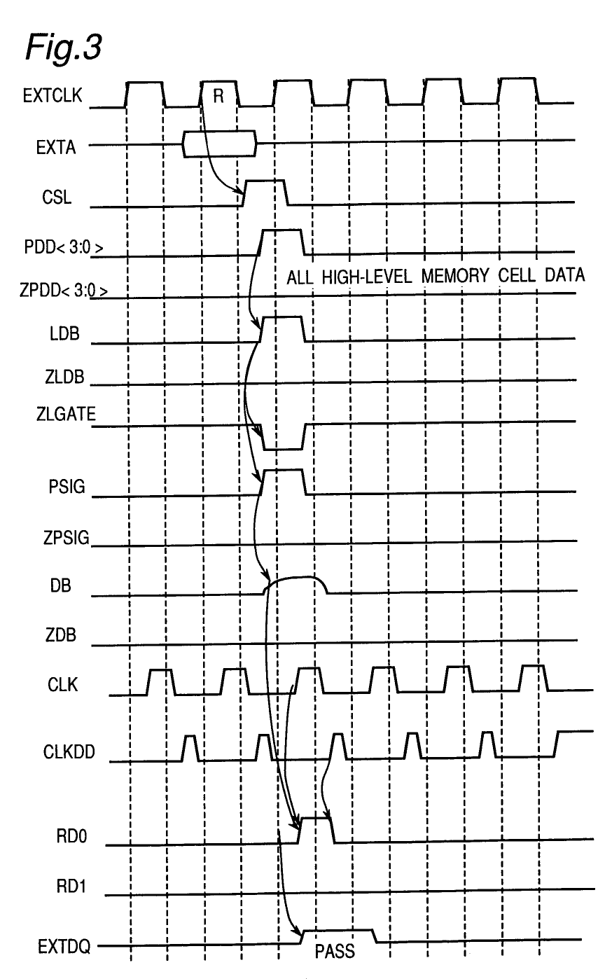

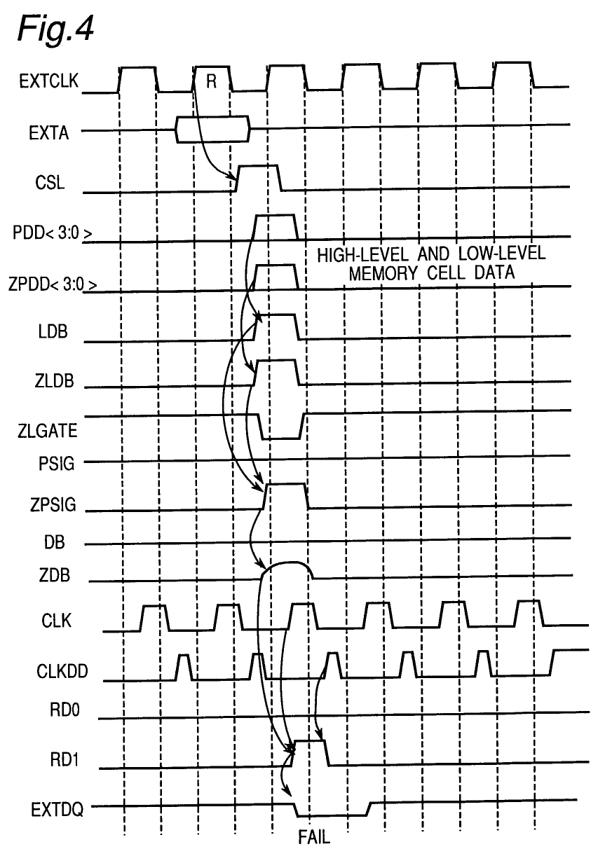

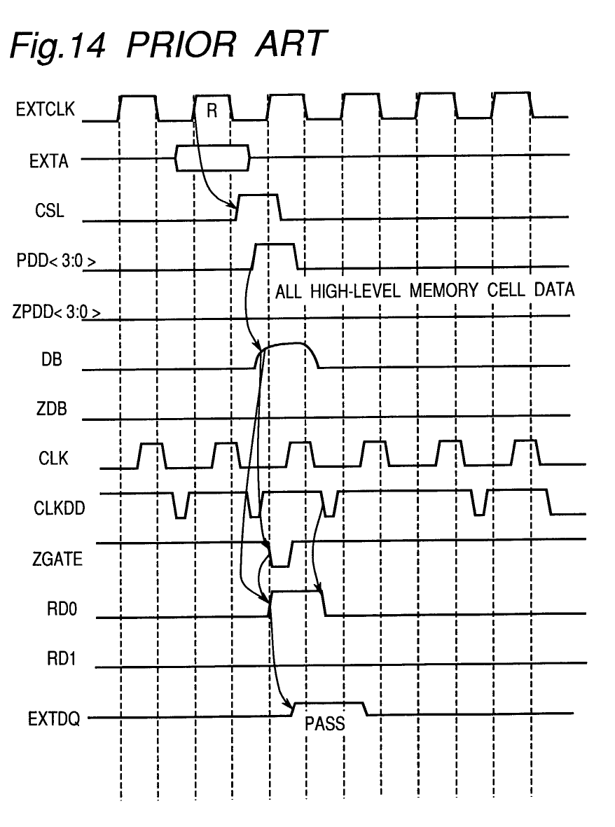

FIGS. 3 and 4 are timing charts at the time of the pass decision and the fail decision in the multi-bit test during operation of the DRAM of FIG. 1 in a CAS latency 2, respectively. Meanwhile, the CAS latency is described later. Hereinafter, such a feature that the multi-bit test of this embodiment is performed at higher speed than prior art is described with reference to the timing chart of FIG. 3. For comparison with the present invention, attention is given to signals DB and CLK in prior art of FIG. 14. In FIG. 14, a time period between a time point of rise of the signal DB to the CMOS level and a time point of the next rise of the signal CLK is about a quarter of a cycle of a signal EXTCLK.

Similarly, also in FIG. 3 of this embodiment, attention is given to the signals DB and CLK. Since the signal DB of FIG. 3 has a small amplitude, a time period between a time point of rise of the signal DB and a time point of the next rise of the signal CLK is approximately equal to a sum of a quarter of a cycle of a signal EXTCLK and α. When the multi-bit test of FIG. 3 of the present invention is compared with a conventional multi-bit test of FIG. 14, the multi-bit test of this embodiment is performed at slightly higher speed than the conventional multi-bit test. However, if capacity of the signal DB becomes large, delay time of the signal DB of FIG. 3 is minute due to the small amplitude of the signal DB in contrast with FIG. 14 in which the signal DB reaches the CMOS level quite belatedly. Therefore, in a device in which capacity of the signal DB is large, such an effect that the multi-bit test is performed at high speed is produced markedly.

In this embodiment, a pass/fail decision of the multi-bit test is made for each pair of the neighboring banks as an example. However, since the present invention is not restricted to this example, the pass/fail decision circuit 20 may also be provided for a combination of a plurality of the banks in which wiring length of the data bus for performing wired OR is reduced to a value similar to that of this example.

(Second Embodiment)

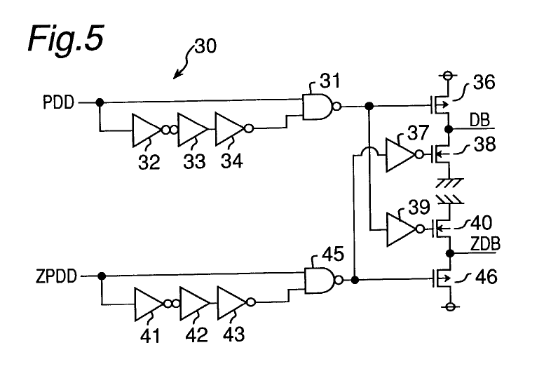

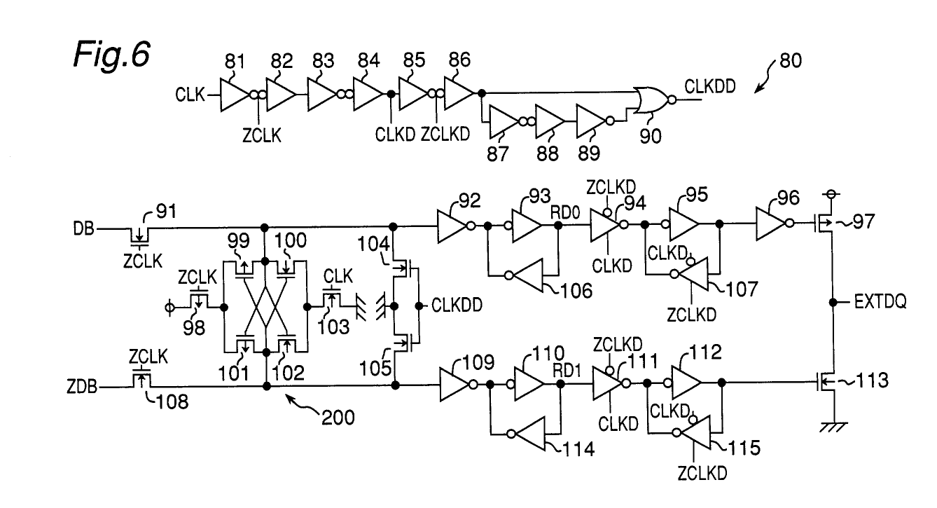

Except for a data bus drive circuit 30 shown in FIG. 5 and a data output circuit 80 shown in FIG. 6, a DRAM acting as a semiconductor memory unit according to a second embodiment of the present invention has a circuit configuration similar to that of the first embodiment of FIG. 1.

Generally, in ordinary operation requiring high-speed operation, data is transmitted on a data bus at a small amplitude. In this embodiment, a result of a pass/fail decision made by the pass/fail decision circuit 20 in the banks is driven by the data bus drive circuit 30 of FIG. 5 at a small amplitude on the data bus pair 10 laid globally on the whole chip and then, is detected by a differential amplifier 200 formed by elements 98 to 103 in the data output circuit 80 of FIG. 6.

Meanwhile, also in the DRAM of this embodiment, since the timing charts of FIGS. 3 and 4 of the first embodiment are applicable likewise, a multi-bit test is performed at higher speed than prior art.

In this embodiment, since data can be delivered at the small amplitude on the data bus pair 10 laid globally on the whole chip, delay of data transmission from each bank to the data output circuit 80 can be restrained.

(Third Embodiment)

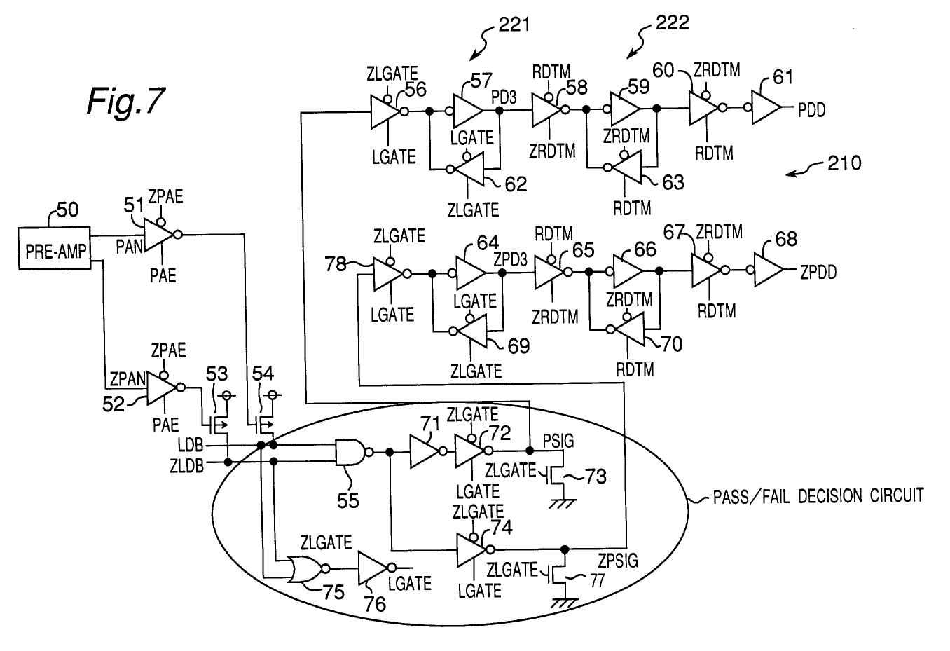

FIG. 7 shows a latency shift circuit 210 of a single data rate synchronous DRAM (SDRSDRAM) acting as a semiconductor memory unit according to a third embodiment of the present invention.

In case read-out in a synchronous DRAM (SDRAM) is performed at high speed, a three-step pipeline system is employed in which a reading operation from address input to output of data at the designated address is divided into three steps by an inputted clock signal and the divided blocks are processed simultaneously. Since three cycles are required from input of a column address to output of data at the designated address in an operation mode of the three-step pipeline system, the operation mode of the three-step pipeline system is referred to as a “column address strobe (CAS) latency 3”. Likewise, since two steps are required from input of the column address to output of data at the designated address in an operation mode of a two-step pipeline system, the operation mode of the two-step pipeline system is referred to as a “CAS latency 2”.

In the latency shift circuit 210 during operation of the SDRAM in the CAS latency 3, data amplified by a pre-amplifier 50 in a memory array is latched for latency shift and is set in a waiting state until a data drive trigger signal is applied to the data bus pair 10. By allocating this waiting time to pass/fail decision of the multi-bit test, the multi-bit test can be performed at an operating frequency identical with that of ordinary operation.

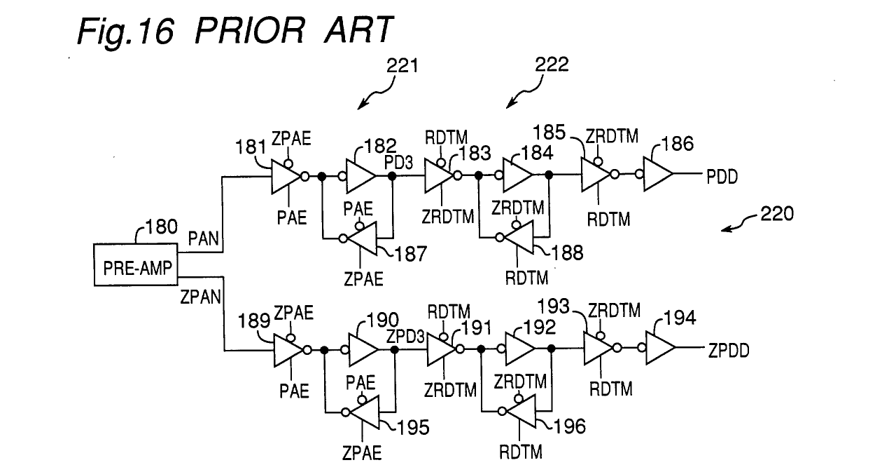

FIG. 16 shows a conventional latency shift circuit 220 during operation in the CAS latency 3. In the conventional latency shift circuit 220, data outputted from a pre-amplifier 180 is latched for latency shift by a first latch circuit 221 and a second latch circuit 222 until a data output trigger signal RDTM to the data bus reaches a high level.

In the latency shift circuit 210 of FIG. 7, this waiting time is utilized for pass/fail decision of the multi-bit test. Namely, data outputted from the preamplifier 50 is immediately outputted to the data bus pair 11 so as to be inputted to the pass/fail decision circuit 20. A pass/fail decision result PSIG of the pass/fail decision circuit 20 is inputted to the latency shift circuit 210. If the pass/fail decision result PSIG can be inputted to the latency shift circuit 210 before the data output trigger signal RDTM reaches a high level, the multi-bit test can be performed at a speed identical with that of ordinary operation.

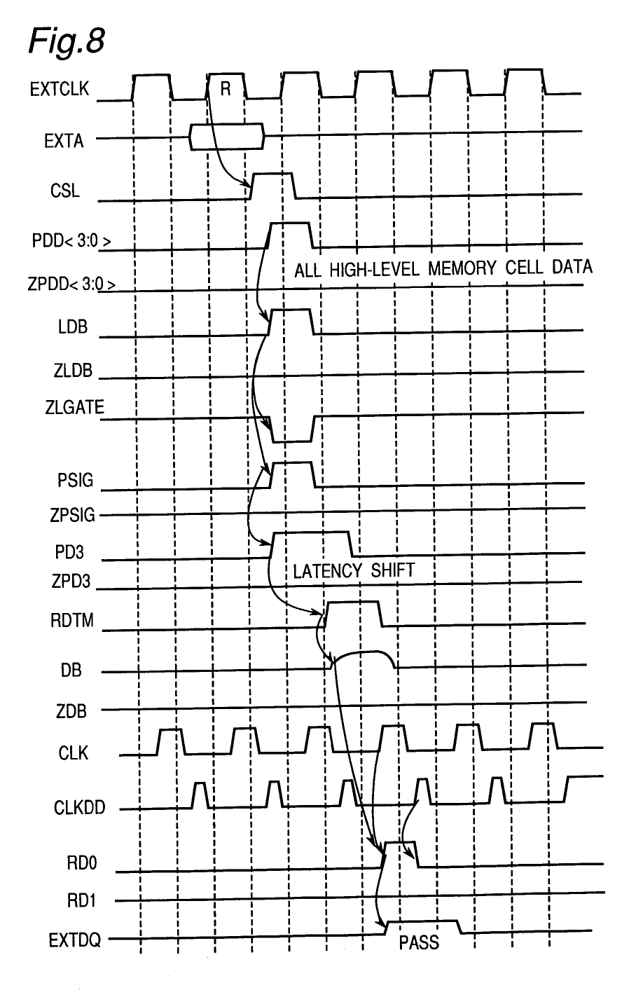

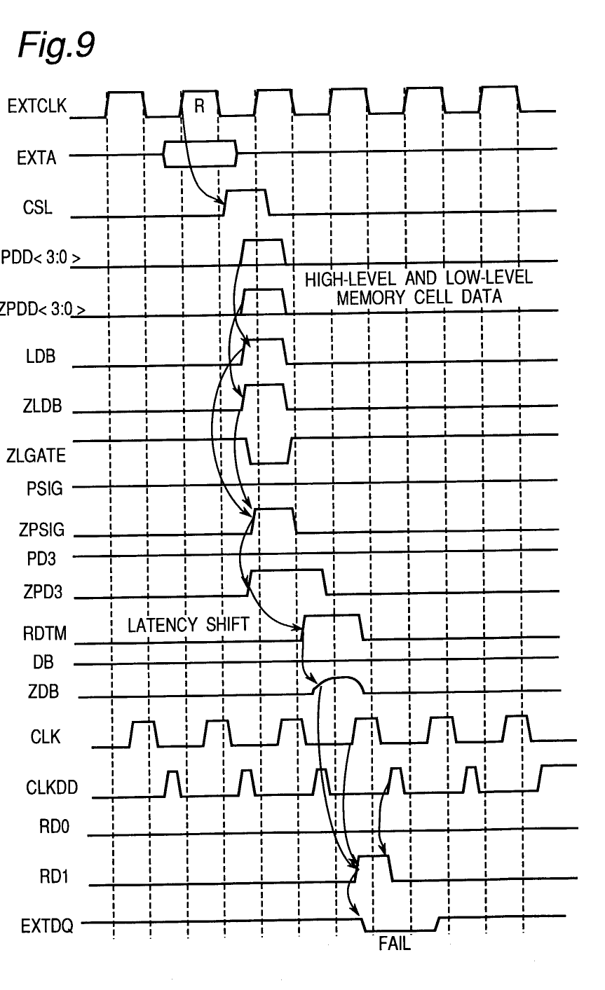

FIGS. 8 and 9 are timing charts at the time of the pass decision and the fail decision in the multi-bit test during operation of the SDRSDRAM of this embodiment in the CAS latency 3, respectively. Hereinafter, such a feature that the multi-bit test during operation of the SDRSDRAM in the CAS latency 3 in this embodiment is performed at far higher speed than prior art is described with reference to the timing chart of FIG. 8. In FIG. 8, a time period from rise of the pass/fail decision result PSIG of the multi-bit test to rise of the data output trigger signal RDTM is a waiting time for latency shift during operation of the SDRSDRAM in the CAS latency 3. In FIG. 8, since this waiting time is equal to about a half of a cycle of a signal EXTCLK, the multi-bit test can be further speeded up by this amount during operation of the SDRSDRAM in the CAS latency 3.

As is clear from the foregoing description of the semiconductor memory unit of the present invention, since the bank switching type semiconductor memory unit has a plurality of the memory cell array banks and includes the pass/fail decision circuit which is provided for a plurality of the neighboring ones of the memory cell array banks so as to make the pass/fail decision on the neighboring ones of the memory cell array banks in the multi-bit test, such a marked effect is gained that the multi-bit test can be speeded up.

What is claimed is:

1. A bank switching type semiconductor memory unit having a plurality of memory cell array banks, comprising:
a pass/fail decision circuit which is provided for a plurality of neighboring ones of the memory cell array banks so as to make a pass/fail decision on the neighboring ones of the memory cell array banks in a multi-bit test.

2. A semiconductor memory unit according to claim 1, further comprising:
a data bus drive circuit; and
a data output circuit which includes a differential amplifier;
wherein a result of the pass/fail decision is driven on a data bus by the data bus drive circuit and then, is detected by the differential amplifier.

3. A semiconductor memory unit according to claim 1, which is formed by a single data rate synchronous DRAM (SDRSDRAM) including a latency shift circuit;
wherein when the SDRSDRAM is operated in a column address strobe (CAS) latency 3, a waiting time in the latency shift circuit is allocated to the pass/fail decision.
